(19) United States
(12) Patent Application Publication
(10) Pub. No.: US 2014/0332057 A1
(43) Pub. Date: Nov. 13, 2014

(54) SOLAR MODULE

(71) Applicant: AU Optronics Corporation, HSIN-CHU (TW)

(72) Inventors: Kuan-Wen TUNG, HSIN-CHU (TW); Chiuan-Ting LI, HSIN-CHU (TW); Huang-Chi TSENG, HSIN-CHU (TW); Chun-Ming YANG, HSIN-CHU (TW); Wei-Jieh LEE, HSIN-CHU (TW)

(73) Assignee: AU Optronics Corporation, HSIN-CHU (TW)

(21) Appl. No.: 14/270,473

(22) Filed: May 6, 2014

(30) Foreign Application Priority Data
May 7, 2013 (CN) 201310163646.7

(51) Int. Cl. H01L 31/048

(52) U.S. Cl. CPC H01L 31/0487
USPC 136/251

(57) ABSTRACT

A solar module is disclosed. The solar module includes a back sheet, a transparent substrate, a plurality of solar cells disposed between the back sheet and the transparent substrate, and an encapsulant for fastening the solar cells therebetween. The back sheet includes a light-receiving surface facing the solar cells, and a back surface opposite to the light-receiving surface. The reflectivity of the light-receiving surface is greater than 90%, and the reflectivity of the back surface is less than 10%. Therefore, the back sheet can have high reflectivity and high thermal radiation rate.

### RELATED APPLICATIONS

This application claims priority to Chinese Application Serial Number 201310163646.7, filed May 7, 2013, which is herein incorporated by reference.

### BACKGROUND

1. Field of Invention

The present invention relates to a solar module.

2. Description of Related Art

Recently, the worldwide storage of crude oil is decreased year by year. The energy issue becomes the world-concerned problem today. To solve the crisis of energy shortage, the development and utilization of various alternate energy sources is an urgent matter. Following the trend of environmental consciousness, the solar energy becomes a center stage in the related field because the solar energy possesses the advantages of non-pollution and unlimited resource. Therefore, the solar cell panel is frequently utilized in, for example, the roof of a building, the square or any other place with full of sunshine.

A solar module includes a plurality of the solar cells, an encapsulant, a back sheet and a frame which the above mentioned components are mounted on. The generating efficiency of a solar module is related to the temperature thereof. The higher the temperature of the solar module is, the less the efficiency of the energy conversion is. However, the utilization of additional active heat dissipation will increase the cost of the solar module and results in additional consumption of electric power.

Thus, there is a need to improve the efficiency of heat dissipation for a solar module without increasing the cost and the weight.

### SUMMARY

One aspect of this disclosure provides a solar module having passive mechanism of heat dissipation.

According to one embodiment of this invention, a solar module is provided. The solar module includes a back sheet, a transparent substrate, plural solar cells disposed between the back sheet and the transparent substrate, and an encapsulant for fastening the solar cells therebetween. The back sheet includes a light-receiving surface facing the solar cells, and a back surface opposite to the light-receiving surface. The reflectivity of the light-receiving surface is greater than 90%, and the reflectivity of the back surface is less than 10%.

In one or various embodiments of this invention, the back sheet may include a low reflectivity substrate having the back surface, wherein the light-receiving surface is coated by a high reflectivity material which the reflectivity thereof is greater than 90%.

In one or various embodiments of this invention, the back sheet may include a high reflectivity substrate having the light-receiving surface, wherein the back surface is coated a low reflectivity material which the reflectivity thereof is less than 10%.

In one or various embodiments of this invention, the back sheet includes a core layer, a first layer attached to one surface of the core layer, and a second layer attached to the other surface of the core surface. The first layer faces the solar cells and its reflectivity is greater than 90%. The reflectivity of the second layer is less than 10%.

In one or various embodiments of this invention, the back sheet has plural micro structures.

In one or various embodiments of this invention, the solar cells are connected in series by plural solder bands.

According to another embodiment of this invention, a solar module is provided. The solar module includes a back sheet, a bottom encapsulant disposed on the back sheet, plural solar cells disposed on the bottom encapsulant, an upper encapsulant disposed on the solar cells, and a transparent substrate disposed on the upper encapsulant. The reflectivity of the back sheet is less than 10%, while that of the bottom encapsulant is greater than 90%.

In one or various embodiments of this invention, the solar module includes a back sheet, a bottom encapsulant disposed on the back sheet, plural solar cells disposed on the bottom encapsulant, an upper encapsulant disposed on the solar cells, and a transparent substrate disposed on the upper encapsulant. The reflectivity of the bottom encapsulant is greater than 90%. The back sheet includes a core layer, a first layer attached to one surface of the core layer, and a second layer attached to the other surface of the core surface. The first layer faces the solar cells and its reflectivity is greater than 90%. The reflectivity of the second layer is less than 10%.

In one or various embodiments of this invention, the back sheet has a back surface opposite to the solar cells. The back surface has plural micro structures.

In one or various embodiments of this invention, the solar cells are connected in series by plural solder bands.

The back surface of the back sheet in the solar module possesses a low reflectivity and the heat dissipation is improved so that the heat radiation dissipation of the solar module is improved. That is, according to this invention, a passive mechanism of heat dissipation is provided without increasing the weight of the solar module. The efficiency of heat dissipation for the solar module is significantly improved.

These and other features, aspects, and advantages of the present invention will become better understood with reference to the following description, drawings and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-section view of a solar module according to a first embodiment of this invention;

FIG. 2 is a cross-section view of a solar module according to a second embodiment of this invention;

FIG. 3 is a cross-section view of a solar module according to a third embodiment of this invention;

FIG. 4 is a cross-section view of a solar module according to a fourth embodiment of this invention;

FIG. 5 is a cross-section view of a solar module according to a fifth embodiment of this invention;

FIG. 6 is a diagram showing the simulation result about the relation between the heat reflectivity of the back sheet and the temperature of the solar cell in a solar module; and

FIG. 7A and FIG. 7B are diagrams illustrating the data of the solar modules respective to the dark-colored back surface of the back sheet and the light-colored back surface of the back sheet during the utilization for 18 days.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts. After understanding the preferred embodiment of this invention, a skilled person in the art may readily make any change and modification according to the technology introduced herein without departing from the spirit and scope of this invention.

In order to increase the usage of sunshine and improve the power generating efficiency of a solar module, the conventional solar module utilizes a light-colored back sheet with higher reflectivity so that the sunshine illuminating on the back sheet may be reflected to the solar cells and be reused. However, even the light-colored back sheet of the solar module has the advantage of high reflectivity, the heat radiation dissipation thereof is worse. Therefore, the power generating efficiency of this kind solar module is difficult to be improved.

In this disclosure, a solar module with two-colored back sheet is provided to match the requirements of high reflectivity and high heat dissipation.

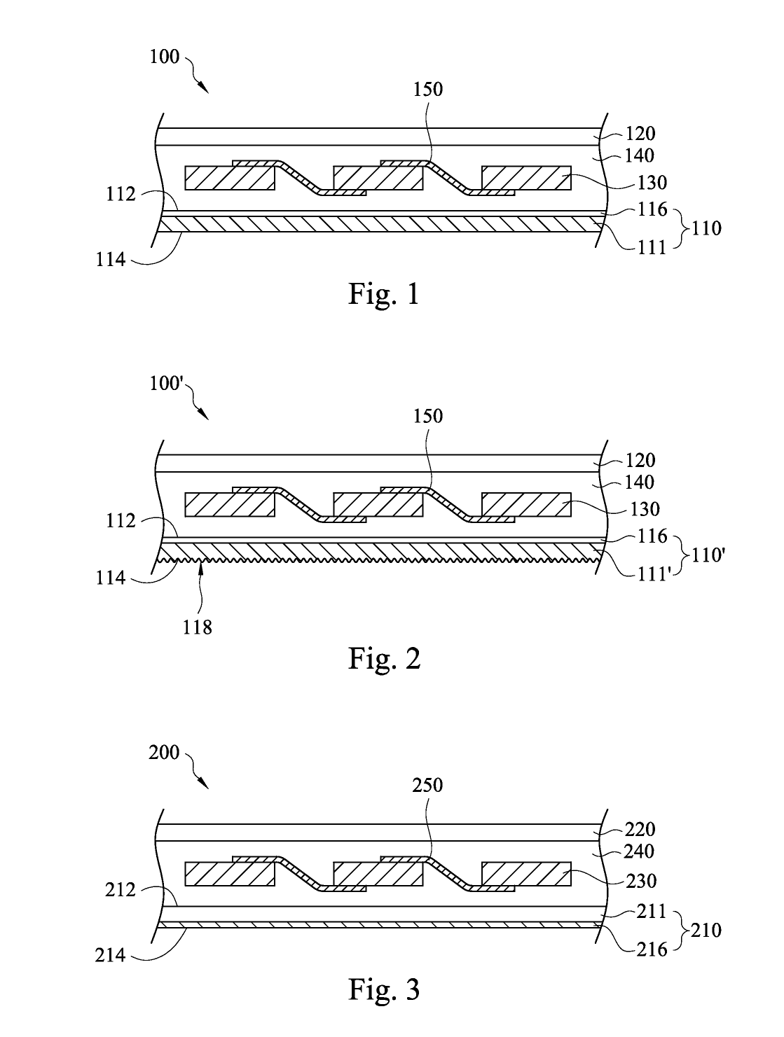

FIG. 1 is a cross-section view of a solar module according to the first embodiment of this invention. The solar module 100 includes a back sheet 110, a transparent substrate 120, a plurality of solar cells 130 and an encapsulant 140. The solar cells 130 are disposed between the back sheet 110 and the transparent substrate 120, while the encapsulant 140 is utilized to fasten the solar cells 130 therebetween. The back sheet 110 includes a light-receiving surface 112 facing the solar cells 130, and a back surface 114 opposite to the light-receiving surface 112. The reflectivity of the light-receiving surface 112 is greater than 90%, and the reflectivity of the back surface 114 is less than 10%. The values of the reflectivity may be measured by an optical spectrometer, for example, LAMBDA 750S.

In other words, the light-receiving surface 112 of the back sheet 110 facing the solar cells 130 is a light-colored surface with higher reflectivity. The back surface 114 of the back sheet 110 is a dark-colored surface with better efficiency of heat dissipation (high thermal radiation rate). Therefore, the solar module 100 may possess both advantages of high reflectivity and high heat dissipation.

Practically, the back sheet may include a single-colored substrate 111, which is coated by a coating with another color on one surface of the single-colored substrate 111, so that the color of the light-receiving surface 112 is different from that of the back surface 114. For example, in this embodiment, the back sheet 100 may include a low reflectivity substrate 111, and the reflectivity thereof is less than 10%. The low reflectivity substrate 111 is coated by a high reflectivity material 116 on the light-receiving side and the reflectivity of the high reflectivity material 116 is greater than 90%. Therefore, the specific back sheet 110 is obtained which the light-receiving surface 112 thereof has high reflectivity and the back surface 114 thereof has low reflectivity.

Besides, because the light-receiving surface 112 of the substrate 111 may possess a certain roughness during the coating of the high reflectivity material 116 on the light-receiving surface 112 of the low reflectivity substrate 111, the reflection ability of the light-receiving surface 112 may be further improved. More particularly, the roughness of the light-receiving surface 112 may increase the reflection ability of the back sheet 110 so that the light illuminating on the back sheet 110 may be reflected to the transparent substrate 120. The light may illuminate on the solar cells 130 again by the reflection of the transparent substrate 120 such that the light may be absorbed by the solar cells again. The usage rate of the light may be improved.

The transparent substrate 120 may be a glass substrate or other transparent plastics. The encapsulant 140 may include ethylene vinyl acetate resin (EVA), low density polyethylene (LDPE), high density polyethylene (HDPE), Silicone, Epoxy, Polyvinyl Butyral (PVB), Thermoplastic Polyurethane (TPU), or the combination thereof, but not limited to these materials above.

The solar module 100 further includes a plurality of solder bands 150 which are utilized to connect the solar cells 130 in series in order to improve the output power of the solar module 100.

This design of the solar module 100 may not need any active mechanism of heat dissipation and the weight of the solar module will not be increased, neither. The temperature of the solar cells 130 may be effectively reduced so that the efficiency of photo-electric conversion may be enhanced.

FIG. 2 is a cross-section view of a solar module according to the second embodiment of this invention. The difference between this embodiment and the first embodiment is: in order to further enhance the efficiency of heat dissipation for the back sheet 110′, a plurality of micro structures (e.g. micro trenches) may be formed on the back surface 114 of the low reflectivity substrate 111′ in advance to increase the roughness of the back surface 114 so that the area of heat exchange and the air convection ability are both enhanced and the efficiency of heat dissipation is then improved. Moreover, the brightness of the back surface 114 may be changed by adjusting the roughness of the back surface 114. In general, the back surface 114 with roughness (Ra) less than 0.5 micron makes the color brighter. Otherwise, the more the roughness of the back surface 110′ is, the darker the color is. In order to enhance the heat radiation efficiency of the back surface 114, more roughness of the back surface 114 and darker color thereof are preferred.

FIG. 3 is a cross-section view of a solar module according to the third embodiment of this invention. The solar module 200 includes a back sheet 210, a transparent substrate 220, plural solar cells 230, an encapsulant 240, and a plurality of solder bands 250 to connect the solar cells 230 in series. The solar cells 230 are disposed between the back sheet 210 and the transparent substrate 220, and the encapsulant 240 is utilized to fasten the solar cells 230 therebetween. The back sheet 210 has a light-receiving surface 212 facing the solar cells 230, and a back surface 214 opposite to the light-receiving surface 212. The reflectivity of the light-receiving surface 212 is greater than 90%, and the reflectivity of the back surface 214 is less than 10%.

In this embodiment, the back sheet may include a high reflectivity substrate 211 which is coated by a low reflectivity material 216 on the back side of the high reflectivity substrate 211. The reflectivity of the high reflectivity substrate 211 is greater than 90%, while the reflectivity of the low reflectivity material 216 is less than 10%. Therefore, the specific back sheet 210 is obtained which the light-receiving surface 212 thereof has high reflectivity and the back surface 214 thereof has low reflectivity.

In foregoing description, micro structures (e.g. micro trenches) may be optionally formed on the back surface 214 of the back sheet 210 such that the air convection ability and the heat exchange area are further enhanced. The low reflectivity material 216 may be optionally doped by a material for heat radiation exchange, for example, ceramics or carbon-silicon oxide mesopore composite materials. The materials may store heat and enhance the effect of infrared emission (thermal radiation).

In addition to utilizing the single-colored substrate with different-colored coating to obtain a two-colored substrate, the solar module may possess the advantages of high reflectivity and high thermal radiation rate by other methods. The following content will be described in detail by accompanying different embodiments.

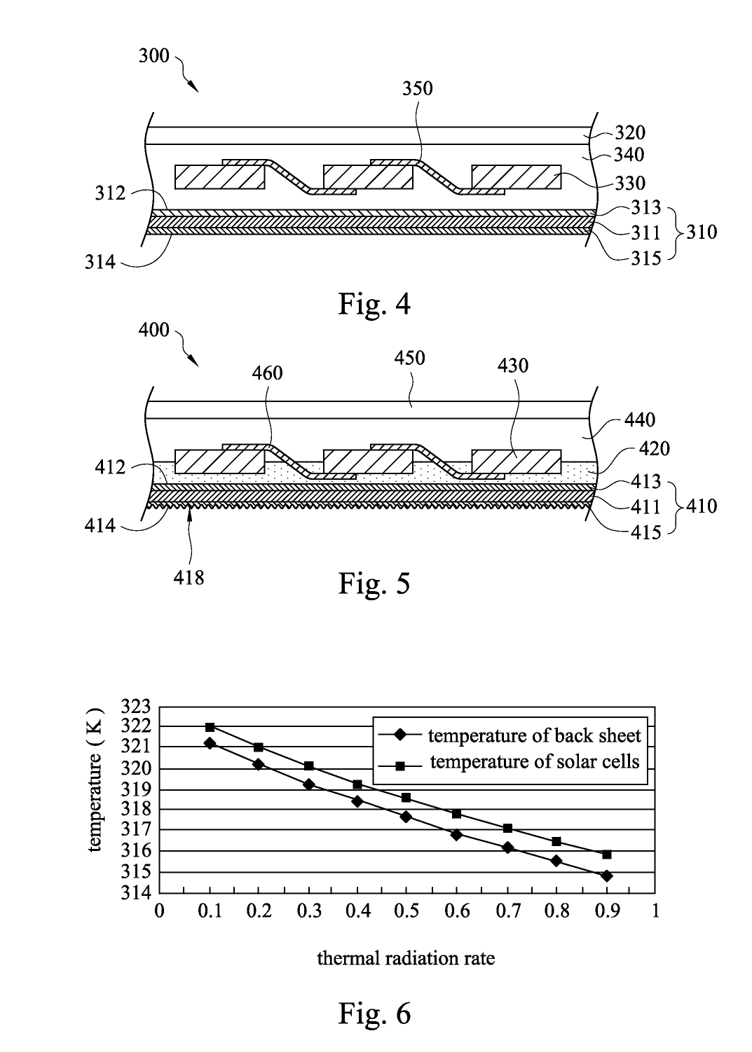

FIG. 4 is a cross-section view of a solar module according to the fourth embodiment of this invention. The solar module 300 includes a back sheet 310, a transparent substrate 320, plural solar cells 330, an encapsulant 340, and a plurality of solder bands 350 to connect the solar cells 330 in series. The solar cells 330 are disposed between the back sheet 310 and the transparent substrate 320 and the encapsulant 340 is utilized to fasten the solar cells 330 therebetween. The back sheet 310 has a light-receiving surface 312 facing the solar cells 330, and a back surface 314 opposite to the light-receiving surface 312. The reflectivity of the light-receiving surface 312 is greater than 90%, and the reflectivity of the back surface 314 is less than 10%.

In this embodiment, the back sheet 310 is a structure of stacked layers, and the back sheet 310 includes a core layer 311, an inner weather-resistant layer 313 attached to one surface of the core layer 311, and an outer weather-resistant layer 315 attached to the other surface of the core layer 311. The inner weather-resistant layer 313 is attached to the inner surface of core layer 311 (i.e. the surface facing the solar cells 330), while the outer weather-resistant layer 315 is attached to the surface of the core layer 311 opposite to the solar cells 330. The reflectivity of the inner weather-resistant layer 313 is greater than 90%, while that of the outer weather-resistant layer 315 is less than 10%.

The core layer may be made of PET. The materials of the inner weather-resistant layer 313 and the outer weather-resistant layer 315 may be Tedlar (produced by DuPont) or other fluoric weather-resistant layer. The inner weather-resistant layer 313 is selected from a light-colored Tedlar with higher reflectivity, while the outer weather-resistant layer 315 is selected from a dark-colored Tedlar with lower reflectivity. The inner weather-resistant layer 313 and the outer weather-resistant layer 315 are attached to the opposite sides of the core layer 311 respectively. Otherwise, selecting PET as the core layer 311 as above, the fluoric materials are then formed on the surfaces of the core layer 311 by coating the fluoric materials on the opposite sides, wherein the inner weather-resistant layer 313 has the reflectivity greater than 90%, and the outer weather-resistant layer 315 has reflectivity less than 10%. The back surface 314 of the outer weather-resistant layer 315 may optionally form a plurality of micro structures thereon. The back sheet 310 with different reflectivity on opposite sides is obtained by combining the core layer with Tedlar layers of different reflectivity. The back sheet possesses the advantages of high reflectivity and high heat radiation thereby.

FIG. 5 is a cross-section view of a solar module according to the fifth embodiment of this invention. The solar module 400 includes a back sheet 410, a bottom encapsulant 420 disposed on the back sheet 410, plural solar cells 430 disposed on the bottom encapsulant 420, an upper encapsulant 440 disposed on the solar cells 430, and a transparent substrate 450 disposed on the upper encapsulant 440. The solar module 400 further includes plural solder bands connecting the solar cells 430 in series. The solar cells 430 are disposed between the bottom encapsulant 420 and the upper encapsulant 440. The bottom encapsulant 420 and the upper encapsulant 440 are bonded by hot pressing such that the back sheet 410, the transparent substrate 450 and the solar cells 430 are fastened.

In this embodiment, the upper encapsulant 440 is preferred to a high transparent material, while the material of the bottom encapsulant 420 may be the same as the upper encapsulant 440 whereas it is opaque and its reflectivity is greater than 90%. The back sheet 410 may be a dark-colored substrate and its reflectivity is less than 10%, as the substrate 111 in the first embodiment. The back sheet 410 also may be a light-colored core layer, and the outer weather-resistant layer 415 may be a dark-colored Tedlar or a coating dark-colored fluoric material. The back surface 414 of the outer weather-resistant layer 415 may optionally form a plurality of micro structures 418 thereon.

Because the bottom encapsulant 420 below the solar cells 430 has a higher reflectivity, the light illuminated thereon may be reflected or scattered to be reused by the solar cells 430. Therefore, the light usage rate of the solar module 400 may be improved, while the back sheet 410 with lower reflectivity may provide higher efficiency of heat radiation. The solar module 400 may possess both advantages of high reflectivity and high thermal radiation rate.

FIG. 6 is a diagram showing the simulation result about the relation between the thermal radiation rate of the back sheet and the temperature of the solar cell in a solar module. As shown in the diagram, the lateral axis represents the thermal radiation rate of the back surface, wherein the thermal radiation rate is negatively related to the reflectivity of the back surface. The vertical axis represents the temperature of the solar cell. From the simulation result, the higher the thermal radiation rate of the back surface is (the reflectivity is lower), the lower the temperature of the solar cell is. In other words, the reflectivity of the back surface may affect the thermal radiation thereof such that the ability of heat dissipation is then different. Inferring from the left boundary value and the right boundary value in the diagram, when the heat radiation rate is increased from 10% to 90%, the output power of the solar module is improved by about 3.05%.

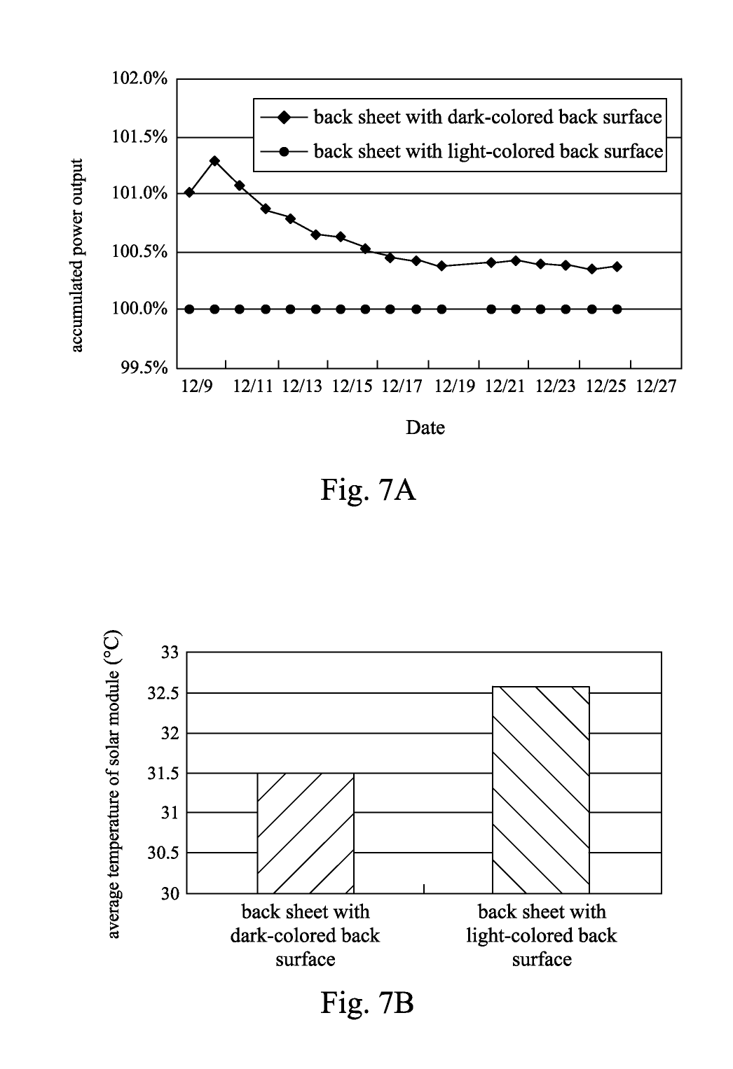

FIG. 7A and FIG. 7B are diagrams illustrating the data of the solar modules respective to the dark-colored back surface of the back sheet and the light-colored back surface of the back sheet during the utilization for 18 days. The accumulated power output of the solar module which utilizes a back sheet with dark-colored back surface is more than that of the solar module which utilizes a back sheet with light-colored back surface by 5%. The temperature of the solar module which utilizes a back sheet with dark-colored back surface is lower than that of the solar module which utilizes a back sheet with light-colored back surface.

To sum up, for a solar module, the back surface of the back sheet having a lower reflectivity may increase the thermal radiation rate such that the heat radiation dissipation of the solar module is improved. In other words, this invention provides a passive mechanism of heat dissipation which may improve the efficiency of heat dissipation of a solar module without increasing the weight thereof.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar module, comprising:
a back sheet;
a transparent substrate;
a plurality of solar cells disposed between the back sheet and the transparent substrate; and
an encapsulant disposed between the back sheet and the transparent substrate for fastening the solar cells therebetween,
wherein the back sheet includes a light-receiving surface facing the solar cells, and a back surface opposite to the light-receiving surface, wherein a reflectivity of the light-receiving surface is greater than 90%, and a reflectivity of the back surface is less than 10%.

2. The solar module of claim 1, wherein the back sheet comprises:
a low reflectivity substrate having the back surface; and
a high reflectivity material disposed on the other surface of the low reflectivity substrate opposite to the back surface, so that the light-receiving surface is formed, wherein a reflectivity of the high reflectivity material is greater than 90%.

3. The solar module of claim 1, wherein the back sheet comprises:
a high reflectivity substrate having the light-receiving surface; and
a low reflectivity material disposed on the other surface of the high reflectivity substrate opposite to the light-receiving surface, so that the back surface is formed, wherein a reflectivity of the low reflectivity material is less than 10%.

4. The solar module of claim 1, wherein the back sheet comprises:
a core layer;
a first layer disposed on one surface of the core layer and facing the solar cells wherein a reflectivity of the first layer is greater than 90%; and
a second layer disposed on the other surface of the core surface, wherein a reflectivity of the second layer is less than 10%.

5. The solar module of claim 1, wherein the back surface of the back sheet has a plurality of micro structures.

6. The solar module of claim 1, wherein the solar cells are connected in series by a plurality of solder bands.

7. A solar module, comprising:
a back sheet, wherein a reflectivity of the back sheet is less than 10%;
a bottom encapsulant disposed on the back sheet, wherein a reflectivity of the bottom encapsulant is greater than 90%;
a plurality of solar cells disposed on the bottom encapsulant;
an upper encapsulant disposed on the solar cells; and
a transparent substrate disposed on the upper encapsulant.

8. The solar module of claim 7, wherein the back sheet comprises:
a core layer;
a first layer disposed on one surface of the core layer and facing the solar cells wherein a reflectivity of the first layer is greater than 90%; and
a second layer disposed on the other surface of the core surface, wherein a reflectivity of the second layer is less than 10%.

9. The solar module of claim 8, wherein the back sheet has a back surface opposite to the solar cells, wherein the back surface has a plurality of micro structures.

10. The solar module of claim 7, wherein the solar cells are connected in series by a plurality of solder bands.
